(19) United States
(12) Patent Application Publication
(10) Pub. No.: US 2017/0012028 A1
(43) Pub. Date: Jan. 12, 2017

(54) RECOVERABLE DEVICE FOR MEMORY BASE PRODUCT

(71) Applicant: Inotera Memories, Inc., Taoyuan City (TW)

(72) Inventors: Tzung-Han LEE, Taipei City (TW); Yaw-Wen HU, Taoyuan City (TW); Neng-Tai SHIH, New Taipei City (TW); Hsu CHIANG, New Taipei City (TW)

(21) Appl. No.: 14/794,828

(22) Filed: Jul. 9, 2015

(51) Int. Cl. H01L 25/10

(52) U.S. Cl. CPC H01L 25/105; H01L 2225/1041; H01L 2225/1058; H01L 2225/1088

(57) ABSTRACT

A recoverable device for memory product includes a substrate, a plurality of device dies and at least one local interconnect layer. The device dies are embedded inside the substrate. The at least one local interconnect layer is disposed on an upper surface of the substrate, and configured to route the device dies to a plurality of electrical terminals on an uppermost surface of the local interconnect layer relative to the substrate.

### BACKGROUND

Field of Invention

The present disclosure relates to a memory product. More particularly, the present disclosure relates to a recoverable device for memory product.

Description of Related Art

With multi-chip packaging, the memory product could be more compactly integrated, and provide a better performance with greater miniaturization. Device dies inside a multi-chip package are typically wire-bonded to each other, and being fixed on the substrate. Therefore, complicated processes are required to form the electrical connections between the device dies in the manufacture of the package of memory product. Furthermore, after the device dies are fixed on the substrate, it is hardly to remove any one of them from the substrate or the package. If a device die inside the package malfunctions, it may jeopardize the whole function of the package, or has to be removed under a procedure with high risks to ruin the whole memory product.

As aforementioned, the available structure of a package with a memory-based product apparently exists inconvenience and defects, and needs further improvement. To address the problems, the ordinarily skilled artisans have been striving to attain a solution, but still not to develop a suitable solution. Therefore, it is important to effectively deal with the problems in the art.

### SUMMARY

The present disclosure provides a recoverable device for memory product. The recoverable device for memory product includes a substrate, a plurality of device dies and at least one local interconnect layer. The device dies are embedded inside the substrate. The at least one local interconnect layer is disposed on an upper surface of the substrate, and configured to route the plurality of device dies to a plurality of electrical terminals on an uppermost surface of the local interconnect layer relative to the substrate.

According to an embodiment of the present disclosure, the substrate has a plurality of die receiving cavities formed within the upper surface of the substrate, and the device dies are embedded inside the die receiving cavities.

According to an embodiment of the present disclosure, the local interconnect layer includes a redistribution layer.

According to an embodiment of the present disclosure, the local interconnect layer includes an interposer layer having a front surface and a back surface, and a plurality of through-silicon vias extending through the interposer layer between the front and back surface.

According to an embodiment of the present disclosure, the local interconnect layer includes a filter layer to route the corresponding device dies to the electrical terminals on the uppermost surface of the local interconnect layer.

According to an embodiment of the present disclosure, the device dies include an active device die and an inactive device die, and the filter layer is configured to route the active device die to the electrical terminals on the uppermost surface of the local interconnect layer.

According to some embodiment of the present disclosure, the filter layer is an uppermost layer of the local interconnect layer relative to the substrate.

According to some embodiment of the present disclosure, the filter layer is disposed between the substrate and an uppermost layer of the local interconnect layer relative to the substrate.

According to an embodiment of the present disclosure, the recoverable device for memory product further includes a plurality of semiconductor devices. The semiconductor devices are electrically connected to the corresponding device die among the device dies through the electrical terminals of the local interconnect layer.

According to an embodiment of the present disclosure, the semiconductor devices include a logic device, a control device or both of them.

According to an embodiment of the present disclosure, the recoverable device for memory product further includes a plurality of connection bumps formed on an end of the electrical terminals, in which the semiconductor devices are electrically connected to the electrical terminals through the connection bumps.

According to an embodiment of the present disclosure, the recoverable device for memory product further includes an array redistribution layer disposed on the local interconnect layer to route the corresponding electrical terminals from the underlying local interconnect layer onto an upper surface of the array redistribution layer. The electrical terminals are rearranged into an array of connection pads, and the connection bumps are then formed on the connection pads.

According to an embodiment of the present disclosure, the semiconductor device includes an array of landing pads arranged over a back surface of the semiconductor device. The landing pad among the array of landing pads is configured to be electrically and physically coupled to the corresponding connection bump.

According to an embodiment of the present disclosure, the local interconnect layer further includes an electrical connection to route an electrical connection between the semiconductor devices.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiment, with reference made to the accompanying drawings as follows:

FIG. 1 to FIG. 8 are cross-sectional views of a recoverable device for memory product according to different embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

It will be understood that when an element is referred to as being “on” another element, it can be directly on the other element or intervening elements may be present therebetween. In contrast, when an element is referred to as being “directly on” another element, there are no intervening elements present.

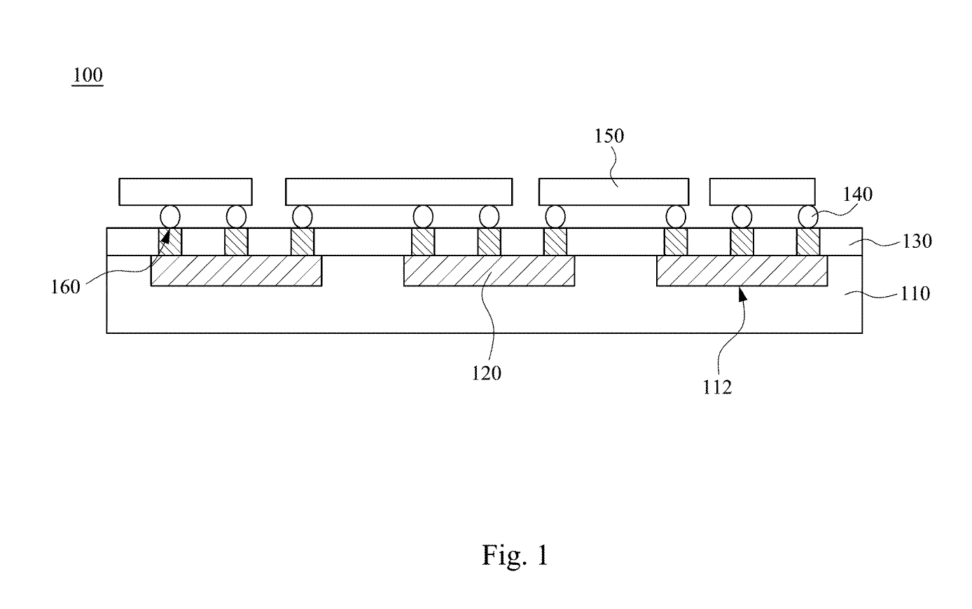

FIG. 1 schematically illustrates a cross-sectional view of a recoverable device 100 for memory product according to an embodiment of the present disclosure. The recoverable device 100 for memory product includes a substrate 110, a plurality of device dies 120 and at least one local interconnect layer 130. The device dies 120 are embedded inside the substrate 110. In some embodiments, the device dies 120 can be attached to the substrate 110. In some embodiments, the substrate 110 may be a memory substrate, a flash memory substrate, a dynamic random access memory (DRAM) substrate, or other memory substrate. The at least one local interconnect layer 130 is disposed on an upper surface of the substrate 110, and configured to route the device dies 120 to a plurality of electrical terminals 160 on an uppermost surface of the local interconnect layer 130 relative to the substrate 110. In consequence, electrical signals can be transmitted between the device dies 120 and the electrical terminal 160 through the local interconnect layer 130. The electrical signals include, for example, input/output (I/O) signals and/or power or ground signals associated with the operation of the device dies 120. In some embodiments, the recoverable device 100 for memory product may further comprises a plurality of connection bumps 140 disposed on the electrical terminals 160 and a plurality of semiconductor devices 150 coupled to the connection bumps 140, both would be described in detail later. In some embodiments, the substrate 110 comprises a plurality of die receiving cavities 112, which would also be described in detail later.

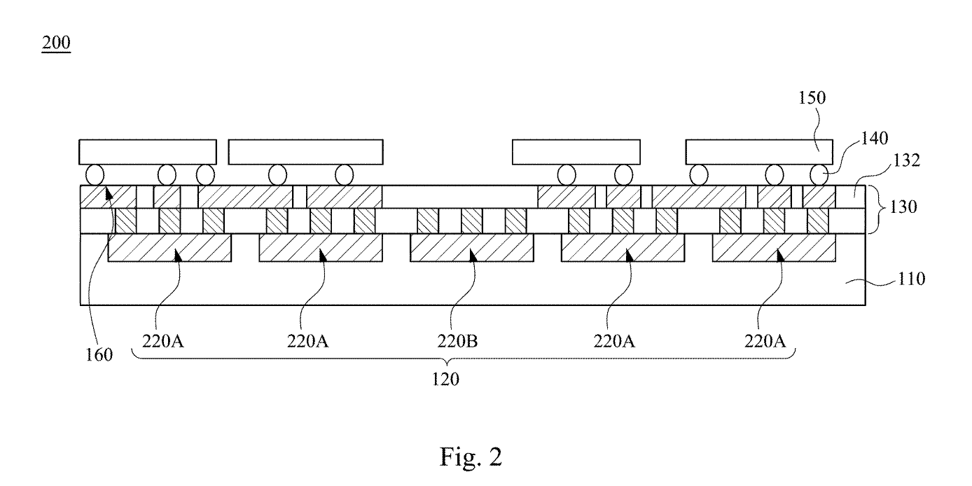

FIG. 2 schematically illustrates a cross-sectional view of the recoverable device 200 for memory product of another embodiment of the disclosure. The recoverable device 200 for memory product includes an active device die 220A, an inactive device dies 220B and a filter layer 132. As shown in FIG. 2, the local interconnect layer 130 further includes a filter layer 132 to route the corresponding device dies 120 among the plurality of device dies 120 to the electrical terminals 160 on the uppermost surface of the local interconnect layer 130. It should be noted that, the filter layer 132 described herein is not intended to limit the structure of the filter layer 132 as a single layer structure, the filter layer 132 may also be a multi-layers structure disposed either discretely or continuously to route the corresponding device die 120 connecting to the electrical terminal 160. That is, a layer among the at least one local interconnect layer 130, which selectively routes the electrical connections of underlying layer to the electrical terminals 160 on the uppermost surface of the local interconnect layer 130, as well as, selectively electrically-connect the device dies 120 and the electrical terminals 160, can be regarded as the filter layer 132. Therefore, the recoverable device 200 for memory product becomes more flexible while applying the filter layer 132.

As shown in FIG. 2, an additional layer, such as the filter layer 132, can be easily fabricated onto the advance layer of the local interconnect layer 130 in the recoverable device 100 for memory product, as shown in FIG. 1, to form a renovated local interconnect layer 130. The electrical terminals 160 of the renovated local interconnect layer 130 in the recoverable device 200 for memory product may also be transformed into a renovated arrangement, after fabricating the additional layer. Furthermore, either the recoverable device 100 for memory product or the recoverable device 200 for memory product still can have more additional layers fabricated onto the advance layer of the local interconnect layer 130. Therefore, the recoverable device for memory product with the local interconnect layer 130 can easily achieve various demands of memory product by just modified the layout of the local interconnect layer 130. The local interconnect layer 130 of the recoverable device 100 for memory product simplifies the integrated process of yielding a memory product and improves yield rate and electrical parameters of memory product.

In some embodiments, the device dies 120 include an active device die 220A and an inactive device die 220B. The filter layer 132 is configured to route the active device die 220A to the electrical terminals 160 on the uppermost surface of the local interconnect layer 130. The device die 120 may have a good die or a broken die, which can be determined under testing, so that the recoverable device 200 for memory product may need a redundancy device die to prevent the active device die 220A being tested as a broken die. In some embodiments, the inactive device die 220B may act as a redundancy device die reserved for the active device dies 220A. When the active device dies 220A is found out being broken, the local interconnect layer 130 can route an electrical connection for a good device die among the inactive device die 220B to replace the broken active device dies 220A. Therefore, the inactive device die 220B become another active die 220A. In some embodiments, the active device die 220A and the inactive device die 220B can be determined either before or after the recoverable device 200 for memory product being diced off the wafer, which offers the recoverable device 200 for memory product more flexibility. In some embodiments, the layout of the filter layer 132 can be determined either before or after the recoverable device 200 for memory product being diced off the wafer, which also offers more flexibility for the recoverable device 200 for memory product.

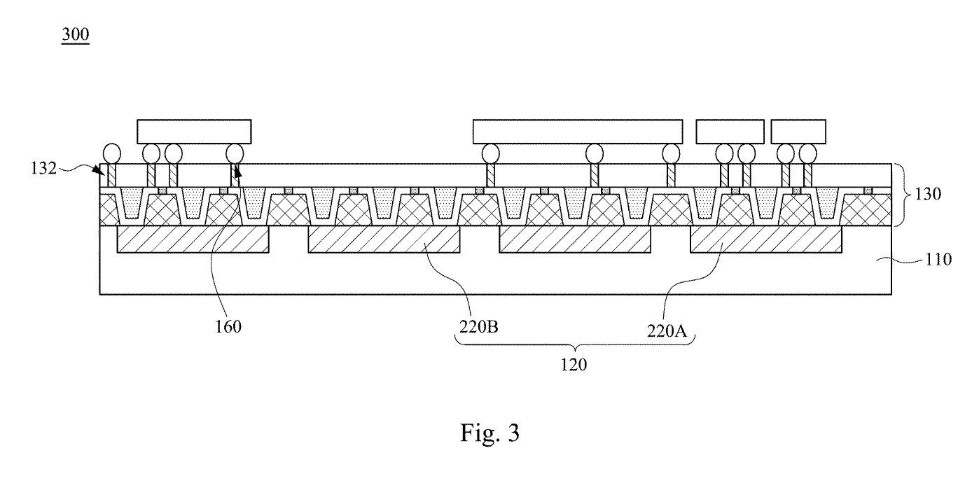

FIG. 3 schematically illustrates a cross-sectional view of an exemplary recoverable device 300 for memory product, in which the filter layer 132 is disposed as the uppermost layer of the local interconnection layer 130. In some embodiments, the filter layer 132 is an uppermost layer of the local interconnect layer 130 relative to the substrate 110. As shown in FIG. 3, the filter layer 132 selectively routes the electrical connections of underlying layer to the uppermost surface of the local interconnect layer 130 and to form the electrical terminals 160, so that the selected device dies 120 are enable to be electrically connected through the electrical terminals 160.

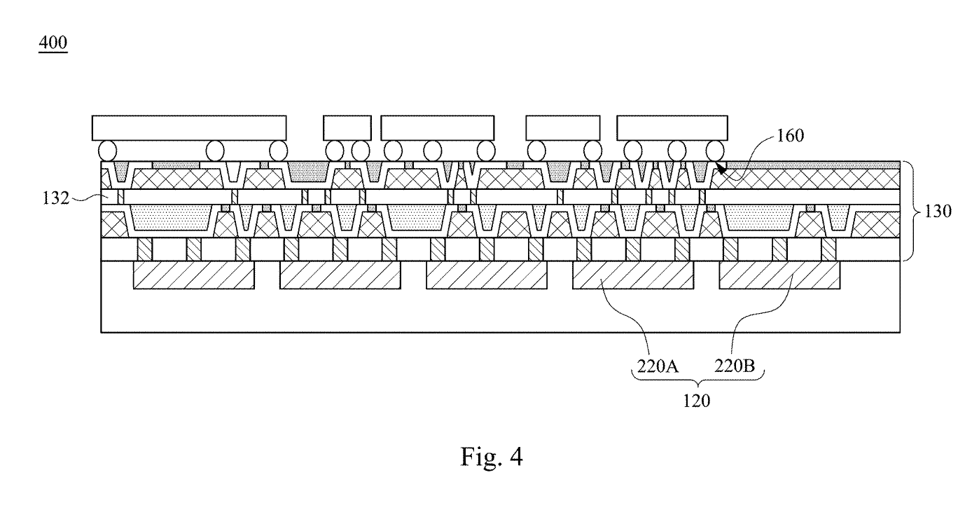

FIG. 4 schematically illustrates a cross-sectional view of an exemplary recoverable device 400 for memory product, in which the filter layer 132 is disposed between the substrate 110 and the uppermost layer of the local interconnection layer 130 relative to the substrate 110. In some embodiments, the filter layer is disposed between the substrate and an uppermost layer of the local interconnect layer relative to the substrate. As shown in FIG. 4, the filter layer 132 is sandwiched between other layers of the local interconnection layer 130, then the filter layer 132 selectively routes the electrical connections of underlying layer to the upper layer, the electrical connections are formed inside the upper layer to route the selected device dies 120 to the electrical terminals 160 on the uppermost surface of the local interconnect layer 130.

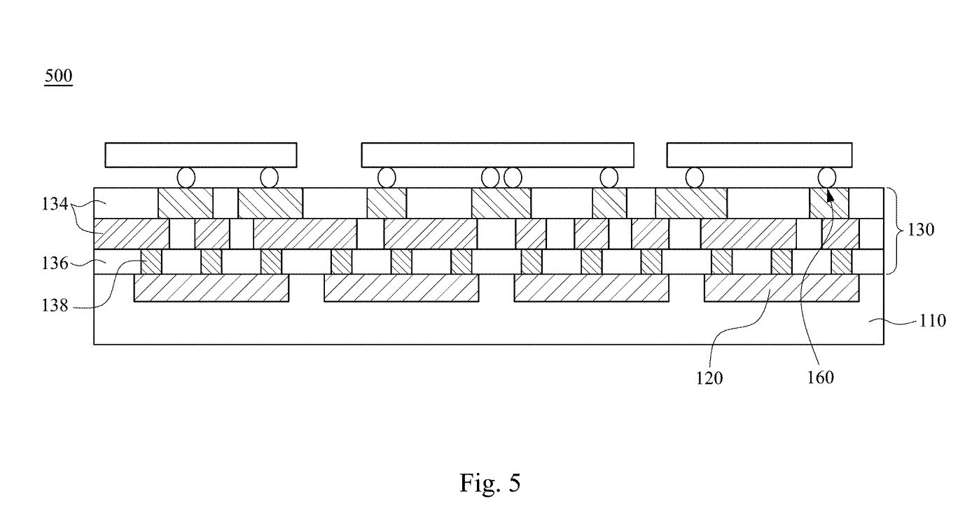

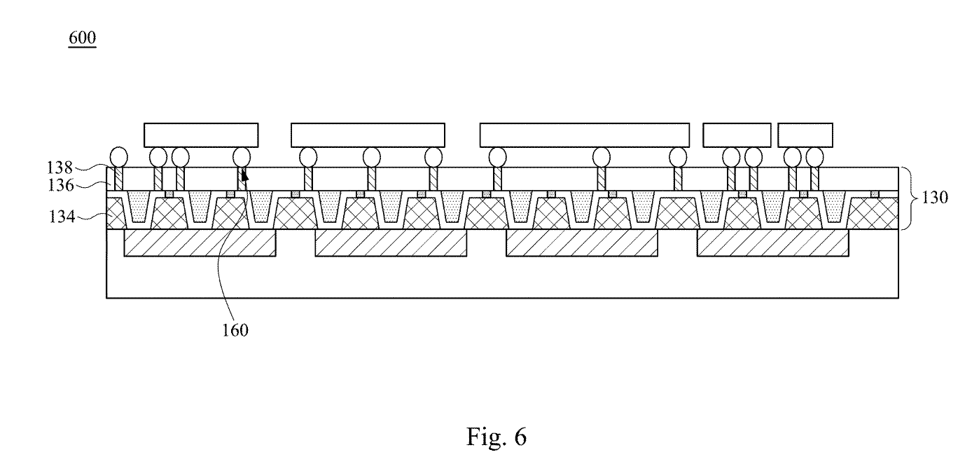

FIG. 5 schematically illustrates a cross-sectional view of an exemplary recoverable device 500 for memory product, in which the local interconnection layer 130 includes a redistribution layer 134 and an interposer layer 136 with through silicon vias 136. FIG. 6 schematically illustrates a cross-sectional view of an exemplary recoverable device 600 for memory product, in which the interposer layer 136 with through silicon vias 136 is disposed on the redistribution layer 134. In some embodiments, the local interconnect layer 130 includes a redistribution layer 134. In some embodiments, the redistribution layer 134 may include one or more metal layers or so on. In some embodiments, the redistribution layer 134 may be produced by single damascene or double damascene process. It should be noted that, the redistribution layer 134 described herein is not intended to limit the structure of the redistribution layer 134, the redistribution layer 134 may have some redistribution traces disposed inside the redistribution layer 134 to transmit the electrical signals, and the redistribution traces are configured to route an electrical connection between sandwiched layers or some electrical connections.

In some embodiments, the local interconnect layer 130 includes an interposer layer 136 having a front surface and a back surface, and a plurality of through-silicon vias (TSVs) 138 extending through the interposer layer 136 between the front and back surface. In some embodiments, the local interconnect layer 130 may include a redistribution layer 134, an interposer layer 136 with through silicon vias 138, other suitable structure providing electrical connections or combination thereof. In some embodiments, the filter layer 132 may be a redistribution layer 134, an interposer layer 136 with through silicon vias 138 or other suitable structure providing electrical connections.

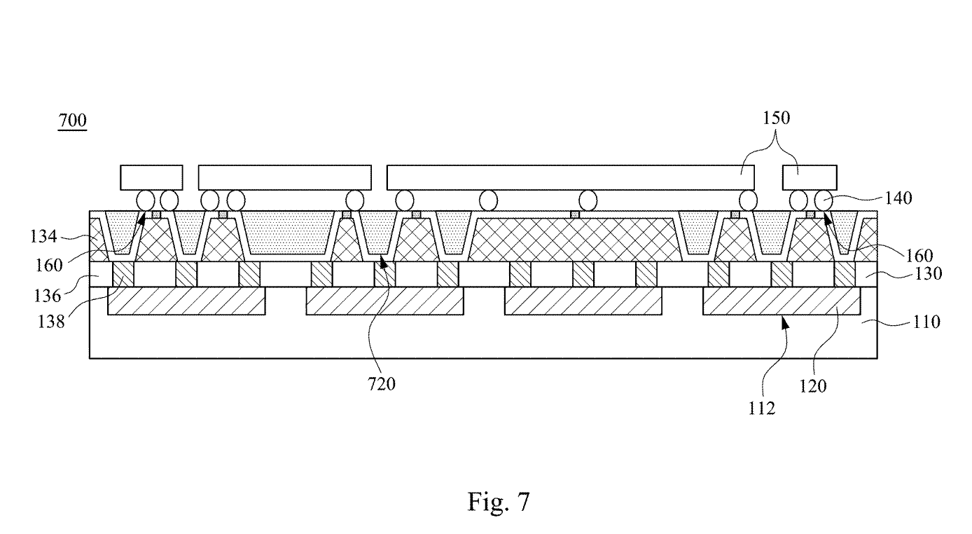

FIG. 7 schematically illustrates a cross-sectional view of an exemplary recoverable device 700 for memory product according to an embodiment of the present disclosure. In some embodiments, the substrate 110 has the plurality of die receiving cavities 112 formed within the upper surface of the substrate 110, and the plurality of device dies 120 are embedded inside the plurality of die receiving cavities 112. In an embodiment, the device dies 120 can be attached to the die receiving cavities 112.

In some embodiments, the recoverable device 700 for memory product further includes a plurality of semiconductor devices 150. The semiconductor devices 150 are electrically connected to the corresponding device die 120 among the plurality of device dies 120 through the electrical terminals 160 of the local interconnect layer 130. In some embodiments, the semiconductor devices 150 may include a logic device, a control device, other suitable processor semiconductor device or combination thereof. In some embodiments, the local interconnect layer 130 further includes an electrical connection 720 to route the electrical signals between the semiconductor devices 150.

In some embodiments, the recoverable device 700 for memory product further includes a plurality of connection bumps 140 formed on an end of the electrical terminals 160, in which the semiconductor devices 150 are electrically connected to the electrical terminals 160 through coupling with the connection bumps 140.

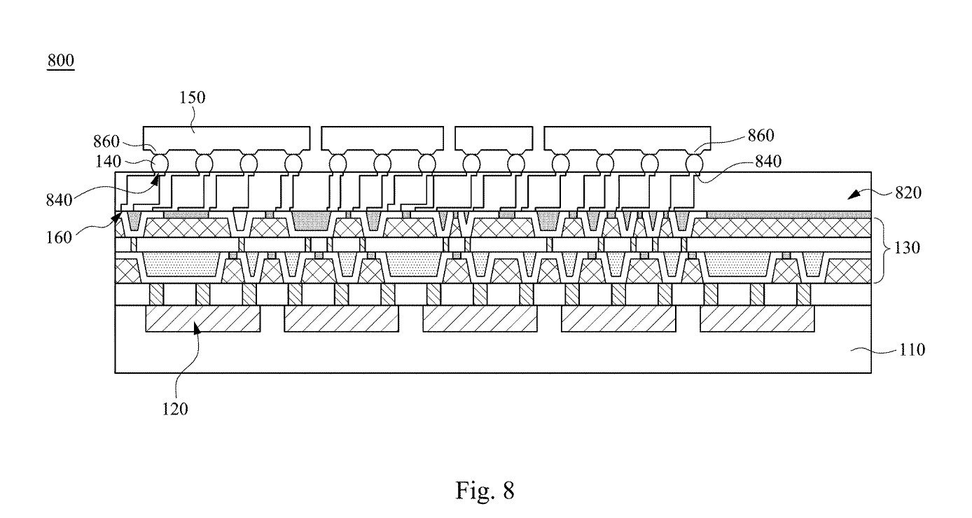

FIG. 8 schematically illustrates a cross-sectional view of an exemplary recoverable device 800 for memory product, in which recoverable device 800 for memory product includes an array redistribution layer 820. In some embodiments, the recoverable device 800 for memory product further includes the array redistribution layer 820 disposed on the local interconnect layer 130 to route the corresponding electrical terminals 160 from the underlying local interconnect layer 130 onto an upper surface of the array redistribution layer 820. In some embodiments, the electrical terminals 160 may be rearranged into an array of connection pads 840 with a specific pattern (not shown), the connection bumps 140 are formed on the connection pads 840.

In some embodiments, the semiconductor devices 150 include an array of landing pads 860 arranged over a back surface of the semiconductor devices 150. The landing pad 860 among the array of landing pads 860 is configured to be electrically and physically coupled to the corresponding connection bump 140.

Summarized from the above description, the present disclosure provides a recoverable device for memory product. The recoverable device for memory product includes a substrate, a plurality of device dies and at least one local interconnect layer. The plurality of device dies are embedded inside the substrate. The at least one local interconnect layer is disposed on an upper surface of the substrate, and configured to route the plurality of device dies to a plurality of electrical terminals on an uppermost surface of the local interconnect layer relative to the substrate. Therefore, the semiconductor device can be electrically connected to the device dies through the electrical terminals.

Although some embodiments of the present disclosure and their advantages have been described in detail, it should be understood that various changes, substitutions, and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, fabricate, composition of matter, means, methods, and steps described in the specification. As one of ordinary skill in the art will readily appreciate from the disclosure of the present disclosure, processes, machines, fabricate, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, fabricate, compositions of matter, means, methods, or steps.

1. A recoverable device for memory product comprising:
a substrate;
a plurality of device dies embedded inside the substrate, wherein the device dies comprise an active device and an inactive device die; and
at least one local interconnect layer, disposed on an upper surface of the substrate, wherein the local interconnect layer comprises a filter layer, configured to selectively route the active die among the device dies to an electrical terminals on an uppermost surface of the local interconnect layer relative to the substrate.

2. The recoverable device for memory product of claim 1, wherein the substrate has a plurality of die receiving cavities formed within the upper surface of the substrate, and the device dies are embedded inside the die receiving cavities.

3. The recoverable device for memory product of claim 1, wherein the local interconnect layer comprises a redistribution layer.

4. The recoverable device for memory product of claim 1, wherein the local interconnect layer comprises an interposer layer having a front surface and a back surface, and a plurality of through-silicon vias extending through the interposer layer between the front and back surface.

5. (canceled)

6. (canceled)

7. The recoverable device for memory product of claim 1, wherein the filter layer is an uppermost layer of the local interconnect layer relative to the substrate.

8. The recoverable device for memory product of claim 1, wherein the filter layer is disposed between the substrate and an uppermost layer of the local interconnect layer relative to the substrate.

9. The recoverable device for memory product of claim 1, further comprising a plurality of semiconductor devices electrically connected to the electrical terminals.

10. The recoverable device for memory product of claim 9, wherein the semiconductor devices comprise a logic device, a control device or the logic device and the control device.

11. The recoverable device for memory product of claim 9, further comprising a plurality of connection bumps formed on an end of the electrical terminals, wherein the semiconductor devices are electrically connected to the electrical terminals through the connection bumps.

12. The recoverable device for memory product of claim 11, further comprising an array redistribution layer disposed on the local interconnect layer to route the corresponding electrical terminals from the local interconnect layer onto an upper surface of the array redistribution layer, wherein the electrical terminals are rearranged into an array of connection pads, and the connection bumps are formed on the connection pads.

13. The recoverable device for memory product of claim 12, wherein the semiconductor devices comprise an array of landing pads arranged over a back surface of the semiconductor devices, wherein the landing pad among the array of landing pads is configured to couple to the corresponding connection bump.

14. The recoverable device for memory product of claim 9, wherein the local interconnect layer further comprises an electrical connection to route an electrical connection between the semiconductor devices.
